(19) United States
(12) Patent Application Publication
(10) Pub. No.: US 2020/0373351 A1
(43) Pub. Date: Nov. 26, 2020

(54) SUBSTRATE ENGINEERING FOR QUBITS

(71) Applicant: Intel Corporation, Santa Clara, CA (US)

(72) Inventors: Jeanette M. Roberts, North Plains, OR (US); Wesley T. Harrison, Portland, OR (US); Adel A. Elsherbini, Chandler, AZ (US); Stefano Pellerano, Beaverton, OR (US); Zachary R. Yoscovits, Beaverton, OR (US); Lester Lampert, Portland, OR (US); Ravi Pillarisetty, Portland, OR (US); Roman Caudillo, Portland, OR (US); Hubert C. George, Portland, OR (US); Nicole K. Thomas, Portland, OR (US); David J. Michalak, Portland, OR (US); Kanwaljit Singh, Rotterdam (NL); James S. Clarke, Portland, OR (US)

(73) Assignee: Intel Corporation, Santa Clara, CA (US)

(21) Appl. No.: 16/635,193

(22) PCT Filed: Sep. 18, 2017
(86) PCT No.: PCT/US2017/051950

§ 371 Date: Jan. 30, 2020

(51) Int. Cl. H01L 27/18; H01L 39/02

(52) U.S. Cl. CPC H01L 27/18; H01L 39/025

(57) ABSTRACT

Embodiments of the present disclosure propose qubit substrates, as well as methods of fabricating thereof and related device assemblies. In one aspect of the present disclosure, a qubit substrate includes a base substrate of a doped semiconductor material, and a layer of a substantially intrinsic semiconductor material over the base substrate. Engineering a qubit substrate in this manner allows improving coherence times of qubits provided thereon, while, at the same time, being sufficiently mechanically robust so that it can be efficiently used in large-scale manufacturing.

### TECHNICAL FIELD

This disclosure relates generally to the field of quantum computing, and more specifically, to substrates for housing qubit devices and circuits, and to methods of fabricating thereof.

### BACKGROUND

Quantum computing refers to the field of research related to computation systems that use quantum mechanical phenomena to manipulate data. These quantum mechanical phenomena, such as superposition (in which a quantum variable can simultaneously exist in multiple different states) and entanglement (in which multiple quantum variables have related states irrespective of the distance between them in space or time), do not have analogs in the world of classical computing, and thus cannot be implemented with classical computing devices.

Quantum computers use so-called quantum bits, referred to as qubits (both terms “bits” and “qubits” often interchangeably refer to the values that they hold as well as to the actual devices that store the values). Similar to a bit of a classical computer, at any given time, a qubit can be either 0 or 1. However, in contrast to a bit of a classical computer, a qubit can also be 0 and 1 at the same time, which is a result of superposition of quantum states≥a uniquely quantum-mechanical phenomenon. Entanglement also contributes to the unique nature of qubits in that input data to a quantum processor can be spread out among entangled qubits, allowing manipulation of that data to be spread out as well: providing input data to one qubit results in that data being shared to other qubits with which the first qubit is entangled.

Compared to well-established and thoroughly researched classical computers, quantum computing is still in its infancy, with the highest number of qubits in a solid-state quantum processor currently being about 10. One of the main challenges resides in protecting qubits from decoherence so that they can stay in their information-holding states long enough to perform the necessary calculations and read out the results.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a schematic illustration of an exemplary qubit substrate, according to some embodiments of the present disclosure.

FIG. 2 provides a schematic illustration of an exemplary qubit device package coupling a qubit substrate with a plurality of electrically conductive vias to a package substrate using first level interconnects, according to some embodiments of the present disclosure.

FIG. 3 is a flow diagram of an illustrative method of manufacturing a qubit substrate, in accordance with various embodiments of the present disclosure.

FIGS. 4A and 4B are top views of a wafer and dies that may include any of the qubit substrates disclosed herein.

FIG. 5 is a cross-sectional side view of a device assembly that may include any of the qubit substrates disclosed herein.

FIG. 6 is a block diagram of an example quantum computing device that may include any of the qubit substrates disclosed herein, in accordance with various embodiments.

### DETAILED DESCRIPTION

### Overview

As briefly described above, quantum computing, or quantum information processing, refers to the field of research related to computation systems that use quantum-mechanical phenomena to manipulate data. One example of quantum-mechanical phenomena is the principle of quantum superposition, which asserts that any two or more quantum states can be added together, i.e. superposed, to produce another valid quantum state, and that any quantum state can be represented as a sum of two or more other distinct states. Quantum entanglement is another example of quantum-mechanical phenomena. Entanglement refers to groups of particles being generated or interacting in such a way that the state of one particle becomes intertwined with that of the others. Furthermore, the quantum state of each particle cannot be described independently. Instead, the quantum state is given for the group of entangled particles as a whole. Yet another example of quantum-mechanical phenomena is sometimes described as a “collapse” because it asserts that when we observe (measure) particles, we unavoidably change their properties in that, once observed, the particles cease to be in a state of superposition or entanglement (i.e. by trying to ascertain anything about the particles, we collapse their state).

Put simply, superposition postulates that a given particle can be simultaneously in two states, entanglement postulates that two particles can be related in that they are able to instantly coordinate their states irrespective of the distance between them in space and time, and collapse postulates that when one observes a particle, one unavoidably changes the state of the particle and its' entanglement with other particles. These unique phenomena make manipulation of data in quantum computers significantly different from that of classical computers (i.e. computers that use phenomena of classical physics). Therefore, both the industry and the academics continue to focus on a search for new and improved physical systems whose functionality could approach that expected of theoretically designed qubits. Physical systems for implementing qubits that have been explored until now include e.g. superconducting qubits (e.g. transmon qubits or simply “transmons”), semiconducting qubits including those made using quantum dots (e.g., spin qubits and charge qubits), photon polarization qubits, single trapped ion qubits, etc.

As also briefly described above, protecting qubits from decoherence remains to be a challenge. For this reason, materials, structures, and fabrication methods used for building quantum circuits continuously focus on reducing spurious (i.e. unintentional and undesirable) two-level systems (TLSs), thought to be a dominant source of qubit decoherence, where, in general, as used in quantum mechanics, a two-level (also referred to as “two-state”) system is a system that can exist in any quantum superposition of two independent and physically distinguishable quantum states. In particular, using substrates of substantially intrinsic (i.e. substantially non-doped) semiconductor materials (e.g. silicon) for housing various qubit devices and circuits has been shown to be favorable for minimizing qubit decoherence and extending qubit lifetime. Such an effect may be attributable to reducing exposure of qubits to TLSs and charge noise by using intrinsic semiconductor substrates. Also, the presence of dopants, unintended particles, and trapped charges can alter the electrostatic environment of electrons in semiconducting qubits, which can degrade qubit performance. Minimizing the presence of dopants can reduce the disruption to the potential energy landscape which can be one of the means used to control the physical location of semiconducting qubits as well as the interaction between qubits. For at least some of these reasons quantum circuits fabricated on a laboratory scale typically use intrinsic silicon substrates. However, such substrates are very fragile. Therefore, while adequate for laboratory use, if fabrication of qubit devices is to be extended to an industrial scale, intrinsic silicon substrates cannot be used because they could easily break in process tools used by leading edge device manufacturers. Mechanical robustness is one of the reasons why such manufacturers typically use doped silicon substrates for building devices and circuits in various classical computing applications. Unfortunately, such doped silicon substrates may not be used in a straight-forward manner for housing qubit devices because doped silicon would significantly degrade qubit lifetime.

Embodiments of the present disclosure propose qubit substrates (i.e. substrates on/in which a plurality of qubits/qubit devices can be provided), as well as methods of fabricating thereof and related device assemblies, that could improve on one or more of the drawbacks described above. In one aspect of the present disclosure, a quantum circuit assembly that includes a qubit substrate and a plurality of qubits provided over or in the qubit substrate is proposed. The qubit substrate may include a base substrate of a doped semiconductor material having a dopant concentration of at least about 1·10¹⁴ atoms per cubic centimeter (atoms·cm⁻³), i.e. the base substrate is a doped semiconductor substrate, and a layer of a substantially intrinsic semiconductor material over the base substrate, the substantially intrinsic semiconductor material having a dopant concentration of less than about 1·10¹² atoms·cm⁻³. Engineering a qubit substrate in this manner allows benefiting from the advantages of using intrinsic and doped semiconductor materials in a substrate for housing qubits, while reducing their respective drawbacks. In particular, such substrates may improve coherence times of qubits provided thereon, e.g. superconducting qubits or spin qubits, while, at the same time, being sufficiently mechanically robust so that they can be efficiently used in large-scale manufacturing.

In the following, a substantially intrinsic semiconductor material as described above will be referred to, simply, as an “intrinsic semiconductor.” In the context of the present disclosure, an intrinsic semiconductor may include any non-doped or low-doped semiconductor materials which are supposed to have low conductivity at typical temperatures at which qubits operate (e.g. currently that is cryogenic temperatures, although such temperatures may increase in the future). A person of ordinary skill in the art would recognize that intrinsic semiconductor layers may sometimes be accidentally doped, e.g. due to the addition of unintentional impurities (e.g., oxygen due to oxidation, residual dopants in processing chambers, etc.) or due to the unintentional doping from the highly conductive neighboring regions by diffusion during subsequent thermal processing. Furthermore, sometimes dopants may be deliberately added to materials for reasons such as e.g. thermal stability. As long as dopants, whether unintentional or deliberately added, in a semiconductor material are in amounts that are low enough so that the semiconductor material may still be considered low-loss and insulating at qubit operating temperatures, such a semiconductor material may be referred to as intrinsic or non-doped.

While some descriptions are provided with reference to superconducting qubits, in particular to transmons, a particular class of superconducting qubits, or to spin qubits, at least some teachings of the present disclosure may be applicable to quantum circuit assembly implementations of any qubits, including superconducting qubits other than transmons and/or including qubits other than superconducting or spin qubits, which may employ qubit substrates as described herein on which qubit devices and circuits are built, all of which implementations are within the scope of the present disclosure. For example, the qubit substrates described herein may be used for housing hybrid semiconducting-superconducting quantum circuits.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, the terms “oxide,” “carbide,” “nitride,” etc. refer to compounds containing, respectively, oxygen, carbon, nitrogen, etc. The terms “substantially,” “close,” “approximately,” “near,” and “about,” generally refer to being within +/- 20% of a target value based on the context of a particular value as described herein or as known in the art.

Furthermore, as used herein, terms indicating what may be considered an idealized behavior, such as e.g. “lossless” or “superconducting,” are intended to cover functionality that may not be exactly ideal but is within acceptable margins for a given application. For example, a certain level of loss, either in terms of non-zero electrical resistance or non-zero amount of spurious TLS's may be acceptable such that the resulting materials and structures may still be referred to by these “idealized” terms. Specific values associated with an acceptable level of loss are expected to change over time as fabrication precision will improve and as fault-tolerant schemes may become more tolerant of higher losses, all of which are within the scope of the present disclosure. Materials described herein as “superconductive/superconducting” may refer to materials, including alloys of materials, which exhibit superconducting behavior at typical qubit operating conditions, e.g. materials which exhibit superconducting behavior at very low temperatures at which qubits typically operate, but which may not exhibit such behavior at e.g. room temperatures. Furthermore, in the following, unless specified otherwise, reference to a superconductive material or circuit element implies that an electrically conductive material that is not superconductive can be used, and vice versa.

Still further, while the present disclosure may include references to microwave signals, this is done only because current qubits are designed to work with such signals because the energy in the microwave range is higher than thermal excitations at the temperature that qubits are typically operated at. In addition, techniques for the control and measurement of microwaves are well known. For these reasons, typical frequencies of qubits are in 1-30 GHz, e.g. in 5-10 GHz range, or 15-25 GHz range, in order to be higher than thermal excitations, but low enough for ease of microwave engineering. However, advantageously, because excitation energy of qubits is controlled by the circuit elements, qubits can be designed to have any frequency. Therefore, in general, qubits could be designed to operate with signals in other ranges of electromagnetic spectrum and embodiments of the present disclosure could be modified accordingly. All of these alternative implementations are within the scope of the present disclosure.

### Engineering Qubit Substrates

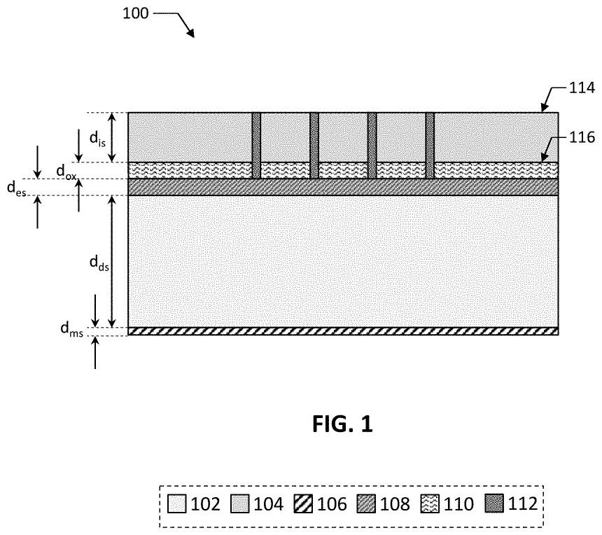

FIG. 1 provides a schematic illustration of an exemplary qubit substrate 100, according to some embodiments of the present disclosure. In various embodiments, the qubit substrate 100 includes at least include a base substrate 102 of a doped semiconductor material and a layer 104 of an intrinsic semiconductor material. In some embodiments, the qubit substrate 100 may further include one or more of a mechanical support layer 106, an electrically conductive shield layer 108, and an oxide layer 110, all of which layers are entirely optional. Furthermore, in any of the embodiments, the intrinsic semiconductor layer 104 may include a plurality of electrically conductive vias 112 extending between a first face 114 and an opposing second face 116 of the intrinsic semiconductor layer 104.

Some of the elements referred in the description of FIG. 1 with reference numerals are indicated in FIG. 1 with different patterns, with a legend showing the correspondence between the reference numerals and patterns being provided at the bottom of FIG. 1, and are not labeled in FIG. 1 with arrows pointing to them in order to not clutter the drawing. For example, the legend illustrates that FIG. 1 uses different patterns to show the base substrate 102, the intrinsic semiconductor layer 104, the mechanical support layer 106, the electrically conductive shield layer 108, the oxide layer 110, and the vias 112.

In some embodiments, the base substrate 102 may include any suitable bulk semiconductor material having a dopant concentration of at least about 1·10¹⁴ atoms per cubic centimeter (atoms·cm⁻³), including all values and ranges therein, e.g. between approximately 1·10¹⁴ and 1·10¹⁹ atoms·cm⁻³, or between about 1.5·10¹⁴ and 1.5·10¹⁶ atoms·cm⁻³. Correspondingly, the base substrate 102 may have resistivity below about 100 ohm·centimeter (Q·cm), including all values and ranges therein, e.g. between about 0.005 and 100 Ω·cm, or between about 8 and 80 Ω·cm. In the present disclosure, unless specified otherwise, resistivity values provided are those at room temperature.

In some embodiments, the base substrate 102 may be a bulk silicon substrate. In other embodiments, the base substrate 102 may be formed using alternative materials, which may or may not be combined with silicon, and which may include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide. Further materials classified as group II-VI, III-V, or IV semiconductor materials may also be used to form the base substrate 102.

In various embodiments, a thickness d_{ds} of the base substrate 102 may be between about 100 and 775 micrometers (um), including all values and ranges therein, e.g. between about 200 and 600 um, or between about 715 and 755 um. The thickness d_{ds} is indicated in FIG. 1, where the subscript “ds” stands for “doped semiconductor.”

Particularly advantageous for large-scale manufacturing may be that the base substrate 102 is one of the commercially available substrates typically used in semiconductor manufacturing, such as e.g. those having a Total Thickness Variation (TTV) less than 1 micron and a wafer bow less than 10 micrometers.

In some embodiments, the intrinsic semiconductor 104 may include a layer of any suitable intrinsic semiconductor material on which a plurality of qubits could be disposed, the intrinsic semiconductor material having a dopant concentration of less than about 1·10¹³ atoms per cubic centimeter (atoms·cm⁻³), including all values and ranges therein, e.g. between about 1·10¹¹ and 3·10¹² atoms·cm⁻³, or between about 9·10¹¹ and 2·10¹² atoms·cm⁻³. Correspondingly, the intrinsic semiconductor 104 may have resistivity of at least about 1000 Ω·cm, including all values and ranges therein, e.g. between about 10000 and 20000 Ω·cm, or between about 8000 and 12000 Ω·cm.

In some embodiments, the intrinsic semiconductor layer 104 may include intrinsic silicon, which may be particularly suitable when the qubits provided thereon are superconducting qubits. In other embodiments, the intrinsic semiconductor layer 104 may be formed using alternative materials, which may or may not be combined with silicon, such as e.g. gallium arsenide, which may be particularly suitable for spin qubits.

In various embodiments, a thickness dᵢₛ of the intrinsic semiconductor layer 104 may be at least about 0.1 um, including all values and ranges therein, e.g. between about 0.1 and 675 um, between about 175 and 575 um, or between about 20 and 60 um. The thickness dᵢₛ is indicated in FIG. 1, where the subscript “is” stands for “intrinsic semiconductor.”

When the qubit substrate 100 is used as a foundation for providing a quantum circuit thereon, a plurality of qubits and at least some of their associated circuitry would be built at the first face 114 of the intrinsic semiconductor layer 104. Exemplary qubits are not specifically shown in FIG. 1 because their configuration and layout depends on the type of qubits being implemented.

For example, if superconducting qubits are implemented, then the qubit substrate 100 would include a plurality of superconducting qubits which include Josephson Junctions, Josephson Junctions being the integral building blocks in superconducting qubit devices, and at least portions of supporting circuitry for a superconducting qubit quantum circuit assembly. In general, a distinction can be made between supporting circuitry elements which are electrically connected to one or more Josephson Junctions of a superconducting qubit, such as e.g. shunt capacitors, superconducting loops of a superconducting quantum interference device (SQUID), etc., referred to herein as “qubit supporting circuitry,” and supporting circuitry elements which are capacitively or magnetically coupled to a qubit but are not directly electrically connected to Josephson Junctions, such as e.g. resonators, flux bias lines, microwave feed lines, etc., referred to herein as “chip supporting circuitry.”

Although not specifically shown in FIG. 1, in some embodiments, both the electrically conductive shield layer 108 and the oxide layer 110 may be absent, in which case the intrinsic semiconductor layer 104 would be provided directly (i.e. in contact with) the base substrate 102. In such embodiments, the base substrate 102 may have a tendency to deform (e.g. form a bow) as a result of a lattice mismatch between the material of the base substrate 102 and the intrinsic semiconductor layer 104. The mechanical support layer 106 provided on the back side of the base substrate 102, as e.g. shown in FIG. 1, may be used to counteract the bow. The mechanical support layer 106 may also be used in the embodiments where one or both of the electrically conductive shield layer 108 and the oxide layer 110 may be present and cause the base substrate 102 to deform in any way.

The mechanical support layer 106 may include any material suitable to counteract the forces exerted on the base substrate 102 due to the presence of the various layers provided thereon. For example, in some embodiments, silicon nitride (SiN) may be used as the mechanical support layer 106. In various embodiments, a thickness dₘₛ of the mechanical support layer 106 may be between about 0.1 and 1 um, including all values and ranges therein, e.g. between about 0.2 and 0.8 um, or between about 0.2 and 0.5 um. The thickness dₘₛ is indicated in FIG. 1, where the subscript “ms” stands for “mechanical support.”

The electrically conductive shield layer 108 may be provided in order to provide electromagnetic shielding for the qubits, readout lines and resonators disposed on or near the first face 114 of the intrinsic semiconductor layer 104 against the potentially negative impacts of radiation to the environment or spurious resonances occurring due to the size of the package or chip enclosure. Additionally, the electrically conductive shield layer 108 may shield the field from the resonators, lines and qubits from the dielectric losses in the underlying substrate 102, thus providing more options for materials of the substrate 102 since it relaxes demands on the substrate in terms of it having to be very low loss. In various embodiments, the conductive shield layer 108 may include any electrically conductive, preferably substantially superconductive, material that can act as such a shield. For example, in some embodiments, the electrically conductive shield 108 may include a doped semiconductor material, in particular a heavily doped semiconductor material having a dopant concentration of at least about 1·10²⁰ atoms·cm⁻³, including all values and ranges therein, e.g. between about 5·10²⁰ and 5·10²¹ atoms·cm⁻³, or between about 1·10²¹ and 2.5·10²¹ atoms·cm⁻³. In such embodiments, dopants could e.g. be boron, gallium, or any other appropriate dopant. In other embodiments, the electrically conductive shield 108 may include one or more metals or metal alloys as typically used in quantum circuits, such as e.g. one or more of aluminum (Al), niobium (Nb), niobium nitride (NbN), titanium nitride (TiN), niobium titanium (NbTi), or niobium titanium nitride (NbTiN), all of which are examples of materials which are superconductive at typical qubit operating temperatures.

In various embodiments, the electrically conductive shield 108 may have resistivity at room temperature below about 250·10⁻⁶ Ω·cm, including all values and ranges therein, e.g. between about 100·10⁻⁶ Ω·cm and 250·10⁻⁶ Ω·cm. A thickness dₑₛ of the electrically conductive shield 108 may be between about 0.2 and 0.5 um, including all values and ranges therein, e.g. between 0.03 and 0.2 um. The thickness dₑₛ is indicated in FIG. 1, where the subscript “es” stands for “electrostatic shield.”

The oxide layer 110, e.g. a layer of silicon oxide (SiO) or aluminum oxide (AlO), may be used in the embodiments where silicon on insulator (SOI) type of substrate is desired, e.g. in order to reduce parasitic capacitance, thereby improving performance of qubit devices. In various embodiments, a thickness dₒₓ of the oxide layer 110 may be between about 20 and 2000 nm, e.g. between about 100 and 500 nm. The thickness dₒₓ is indicated in FIG. 1, where the subscript “ox” stands for “oxide.”

FIG. 1 illustrates an embodiment of the qubit substrate 100 where both the electrically conductive shield layer 108 and the oxide layer 110 are present. In such an embodiment, the base substrate 102 may be in contact with one side of the electrically conductive shield layer 108, while the other side of the electrically conductive shield layer 108 is in contact with one side of the oxide layer 110, and the other side of the oxide layer 110 is in contact with the intrinsic semiconductor 104.

In other embodiments (not specifically shown in FIGS.), the qubit substrate 100 may be such that the electrically conductive shield layer 108 is present while the oxide layer 110 is absent. In such embodiments, the base substrate 102 may be in contact with one side of the electrically conductive shield layer 108, while the other side of the electrically conductive shield layer 108 is in contact with the intrinsic semiconductor 104.

In still other embodiments (not specifically shown in FIGS.), the qubit substrate 100 may be such that the oxide layer 110 is present while the electrically conductive shield layer 108 is absent. In such embodiments, the base substrate 102 may be in contact with one side of the oxide layer 110, while the other side of the oxide layer 110 is in contact with the intrinsic semiconductor 104.

Further, as described above, in some embodiments (not specifically shown in FIGS.), the qubit substrate 100 may be such that both the electrically conductive shield layer 108 and the oxide layer 110 are absent. In such embodiments, the base substrate 102 may be in contact with the intrinsic semiconductor 104.

In some embodiments, the qubit substrate 100 may further include a plurality of electrically conductive vias 112 extending between (i.e. from) the first face 114 of the intrinsic semiconductor layer 104 and the electrically conductive shield layer 108. Thus, the height of the vias 112 is equal to the thickness dᵢₛ plus the thickness dₒₓ. In various embodiment, a width of each via 112 could be less than about 400 um, including all values and ranges therein, e.g. less than 200 um. Typical materials to make the vias 112 electrically conductive include aluminum (Al), niobium (Nb), niobium nitride (NbN), titanium nitride (TiN), molybdenum rhenium (MoRe), and niobium titanium nitride (NbTiN), all of which are particular types of superconductors. However, in various embodiments, other suitable superconductors/conductors and alloys of superconductors/conductors may be used as well. The vias could also be made using a superconducting liner (e.g., TiN) filled with different material such as copper.

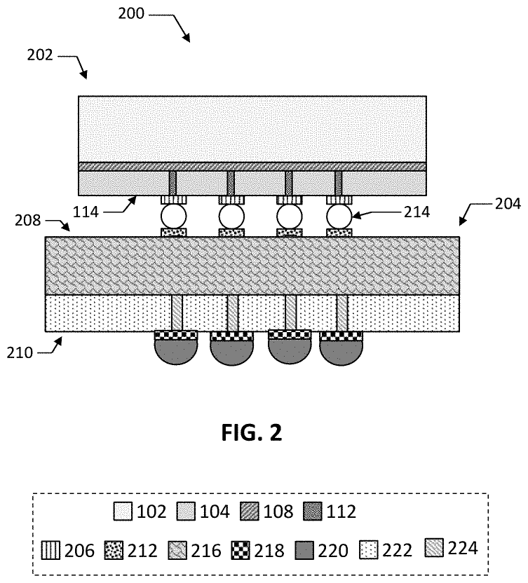

The vias 112 may be advantageously used to provide improved grounding and reduce spurious microwave resonances during qubit operation by being connected to a ground potential of a packaging substrate. An example of connecting a qubit substrate to a packaging substrate is shown in FIG. 2 and described below. Using the vias 112 may be particularly advantageous for some types of qubits, e.g. superconducting qubits, where such vias are typically used when a qubit substrate supports propagation of microwave signals in order to e.g. suppress microwave parallel plate modes, cross-coupling between circuital blocks, and substrate resonant modes. In general, providing ground pathways in the form of the vias 112 may improve signal quality, enable fast pulse excitation and improve the isolation between the different conductive lines of a quantum circuit implementing superconducting qubits. While four conductive vias 112 are shown in FIG. 1, in various embodiments, more or fewer than four vias 112 may be included in the qubit substrate 100.

FIG. 2 provides a schematic illustration of an exemplary qubit device package 200 coupling a qubit substrate 202 with a plurality of electrically conductive vias to a package substrate 204 using first level interconnects, according to some embodiments of the present disclosure. Similar to FIG. 1, some of the elements referred in the description of FIG. 2 with reference numerals are indicated in FIG. 2 with different patterns, with a legend showing the correspondence between the reference numerals and patterns being provided at the bottom of FIG. 2. Moreover, elements of FIG. 2 having reference numerals as those used in FIG. 1 are intended to show the same or analogous elements as those described with reference to FIG. 1, which descriptions are not repeated in the interests of brevity. In particular, the qubit substrate 202 shown in FIG. 2 resembles and illustrates at least some of the same elements as the qubit substrate 100 shown in FIG. 1. In fact, the qubit substrate 202 shown in FIG. 2 could be implemented according to any of the embodiments of the qubit substrate 100 described above which include the plurality of conductive vias 112. While FIG. 2 illustrates that the qubit substrate 202 includes the electrically conductive shield 108 between the intrinsic semiconductor layer 104 and the doped base substrate 102, and does not include the oxide layer 110 or the mechanical support layer 106 described with reference to FIG. 1, in other embodiments of the qubit device package 200 the electrically conductive shield 108 may be excluded and/or one or both of the oxide layer 110 and the mechanical support layer 106 may be present as was described with reference to FIG. 1.

FIG. 2 illustrates that the qubit substrate 202 is flipped upside down, compared to the view shown in FIG. 1, in order to couple the vias 112 extending to the surface 114 of the qubit substrate 202 to the packaging substrate 204, a so-called “flip-chip” configuration. As previously described herein, various quantum circuit components in the form of e.g. a plurality of qubits and supporting circuitry may be proximate to or provided on the first face 114. Conductive pathways (not specifically shown in FIG. 2) may extend over/in the qubit substrate 202 and be coupled between such various quantum circuit components and conductive contacts 206 also disposed at the first face 114. The conductive pathways between the various quantum circuit components and the conductive contacts 206 are not specifically shown in FIG. 2 because the details of quantum circuit components provided on the qubit substrate 202 are not specifically shown in FIG. 2, but could be in the form of e.g. one or more of flux bias lines, microwave lines, or drive lines, in case superconductive qubits are implemented, and may be implemented as conductive vias, conductive lines, and/or any combination of conductive vias and lines. In some embodiments, such conductive pathways are also disposed on the first face 114 of the qubit substrate 202.

As also shown in FIG. 2, the package substrate 202 may include a first face 208 and an opposing second face 210. Conductive contacts 212 may be disposed at the first face 208. FIG. 2 further illustrates first level interconnects 214 coupling the conductive contacts 206 at the first face 114 of the qubit substrate 202 and the conductive contacts 210 at the opposing face of the package substrate 204 (i.e. at the first face 208). FIG. 2 schematically illustrates that the first level interconnects 214 are implemented as solder bumps or balls (shown in FIG. 2 as while circles associated with the conductive contacts 206 and 212), illustrating one manner for implementing first level interconnects in quantum circuit assemblies. For example, the first level interconnects 214 may be flip chip (or controlled collapse chip connection, “C4”) bumps disposed initially on the qubit substrate 202 or on the package substrate 204. In other embodiments, other types of first level interconnects may be used as well and are within the scope of the present disclosure.

How electrical connections are made for various conductive contacts on a qubit substrate and on a package substrate is well-known in the art of packaging and, therefore, in the interests of brevity, not described here in detail. In general, connections are made by providing a metallization stack on, or as a part of, the first face 208 of the package substrate 204, schematically shown as a metallization stack 216 in FIG. 2.

While the conductive contacts 206 and 212 and the first level interconnects 214 are shown in FIG. 2 only for the grounding vias 112, in various embodiments, the quantum circuit package assembly 200 may include additional conductive contacts 206 on the qubit substrate 202 coupled to additional conductive contacts 212 on the package substrate 204 in order to route, during operation of a quantum circuit provided on the qubit substrate 202, electrical signals (such as e.g. power, input/output (I/O) signals, including various control signals for external and internal control of the qubits).

Optionally, conductive contacts 218 may be provided on the second face 210 of the package substrate 204, in case the package substrate 204 is coupled to further components, e.g. a circuit board, using second level interconnects 220. Such further components are not specifically shown in FIG. 2 because connectivity to further components via the second level interconnects 220 is optional. In such embodiments, the package substrate 204 may include an insulating material 222 between the first face 208 and the second face 210, electrically coupling various ones of the conductive contacts 212 to various ones of the conductive contacts 218, in any desired manner, and conductive pathways 224 may extend through the insulating material 222 as shown in FIG. 2 and may include one or more conductive vias, one or more conductive lines, or a combination of conductive vias and conductive lines, for example. In various embodiments, the insulating material 222 may include any suitable material, such as an interlayer dielectric (ILD). Examples of insulating materials may include silicon oxide, silicon nitride, aluminum oxide, carbon-doped oxide, and/or silicon oxynitride. Conductive pathways 224 may include any of the materials described with reference to the vias 112.

When the vias 112 are implemented in a qubit substrate, implementing the electrically conductive shield layer 108 as described herein may be particular advantageous because it allows decreasing the height of the vias 112 as the vias 112 now do not have to extend throughout the entire qubit substrate, but only a portion from the surface of the qubit substrate on which qubits are to be implemented to the conductive shield layer 108. Decreasing the height of the vias 112 advantageously allows decreasing the width of the vias in accordance with the manufacturing considerations related to aspect ratio of which via structures are possible to make. As a result, the vias 112 may take up less total space in the qubit substrate, thus freeing up valuable space on the qubit substrate to implement active elements such as e.g. qubits, and/or more of the vias 112 can be provided, e.g. to ensure improved grounding/shielding. Furthermore, shorter vias advantageously have lower inductance, and the spacing between the individual vias 112 can be made larger while maintaining substantially the same level of suppression and die size as before, which also frees up more space on the qubit substrate to provide active elements.

It should be noted that the advantages of being able to implement shorter vias 112 by virtue of providing the conductive shield layer 108 as described herein may be achieved independently of the qubit substrate being formed of the intrinsic semiconductor layer 104 and the doped base substrate 102 as described herein, and independent of providing the oxide layer 110 and the mechanical support layer 106. In fact, in some embodiments of the present disclosure, the qubit device package 200 as described herein may be implemented where materials of the layer 104 is substantially the same as that of the base substrate 102, and may or may not include one or more of the oxide layer 110 and the mechanical support layer 106.

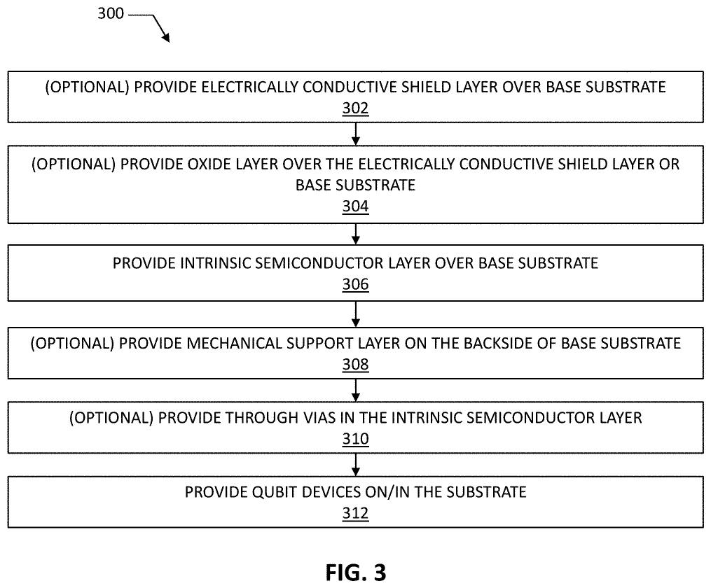

Qubit substrates as described herein, such as e.g. the qubit substrates 100 and 202, may be fabricated using various suitable techniques, all of which being within the scope of the present disclosure. One such exemplary technique is shown in FIG. 3 and described below.

FIG. 3 is a flow diagram of an illustrative method 300 of manufacturing a qubit substrate, e.g. the qubit substrate 100 or 202, in accordance with various embodiments of the present disclosure. Various operations of the method 300 may be illustrated with reference to some exemplary embodiments discussed below, but the method 300 may be used to manufacture any suitable qubit substrates according to any embodiments of the present disclosure.

Although the operations of the method 300 are illustrated in FIG. 3 once each and in a particular order, the operations may be performed in any suitable order and repeated as desired. For example, one or more operations may be performed in parallel to manufacture multiple qubit substrates or/and qubit device packages as described herein substantially simultaneously. In another example, the operations may be performed in a different order to reflect the architecture of a particular quantum circuit component provided on a qubit substrate according to any of the embodiments of the present disclosure.

In addition, the manufacturing method 300 may include other operations, not specifically shown in FIG. 3, such as e.g. various cleaning operations as known in the art. For example, in some embodiments, the base substrate 102 may be cleaned prior to or/and after any of the processes of providing the intrinsic semiconductor layer 104 thereon as described herein, e.g. to remove surface-bound organic and metallic contaminants, as well as subsurface contamination. In some embodiments, cleaning may be carried out using e.g. a chemical solutions (such as peroxide), and/or with ultraviolet (UV) radiation combined with ozone, and/or oxidizing the surface (e.g., using thermal oxidation) then removing the oxide (e.g. using hydrofluoric acid (HF)).

The method 300 may begin with an optional process 302 of providing an electrically conductive shield layer, such as e.g. the electrically conductive shield layer 108 as described herein, over a base substrate of a doped semiconductor material, e.g. the base substrate 102 as described herein, for the embodiments where such a shield layer is implemented. In various embodiments, any suitable deposition techniques may be used for providing the electrically conductive shield layer 108 in the process 302, such as e.g. atomic layer deposition (ALD), physical vapor deposition (PVD) (e.g. evaporative deposition, magnetron sputtering, or e-beam deposition), chemical vapor deposition (CVD), or electroplating, and the electrically conductive shield layer 108 may include any conducting or superconducting material suitable for providing electrical connectivity in a quantum circuit, such as e.g. Al, Nb, NbN, NbTiN, TiN, MoRe, etc., or any alloy of two or more superconducting/conducting materials.

In some embodiments, providing the electrically conductive shield layer 108 as a highly doped semiconductor material may be particularly advantageous as it would allow subsequent epitaxial growth of intrinsic semiconductor material of the intrinsic semiconductor layer 104 thereon at a later process. Thus, in some embodiments, the process 302 may include providing such a heavily doped semiconductor layer using either an implantation/diffusion process or a deposition process on the upper layers of the base substrate 102. In the former process, dopants such as boron, gallium, aluminum, antimony, phosphorous, or arsenic may be ion-implanted into the base substrate 102 to form the highly doped semiconductor layer that may serve as the conductive shield layer 108. An annealing process that activates the dopants and causes them to diffuse farther into the base substrate 102 may follow the ion implantation process. In the latter process, an epitaxial deposition process may provide material that is used to fabricate the highly doped layer. In some implementations, the highly doped layer may be fabricated using a silicon alloy such as silicon germanium or silicon carbide. In some embodiments, the epitaxially deposited semiconductor material, such as e.g. silicon alloy, may be doped in situ with dopants such as boron, arsenic, or phosphorous. In some embodiments, the highly doped layer to serve as the conductive shield layer 108 may be formed using one or more alternate semiconductor materials such as germanium or a group III-V material or alloy. In some embodiments, an etch process may be performed before the epitaxial deposition to create recesses in base substrate 102 in which the material for the highly doped regions to serve as the conductive shield layer 108 is deposited.

To facilitate wafer-to-wafer permanent bonding, in some embodiments, an oxide layer may be present on one of the wafer surfaces to be bonded, and silicon present on the other wafers surface. The two surfaces are then brought into contact with each other. For example, the oxide layer 110 may be grown on one of the silicon wafers, e.g., the backside of the intrinsic wafer 104. The oxide may be thermally grown silicon oxide, e.g. using wet or dry oxidation processes. The oxide on the wafer 104 and the silicon on the substrate wafer 102 will experience an attractive force, e.g. the Van der Waals force. To make a stronger bond heat may be applied, e.g. a temperature up to about 600 degrees Celsius, e.g., between about 400 and 500 degrees Celsius. The heat may help removing at least some of the hydroxyl groups (OH) or water present between the two surfaces. In other embodiments, the oxide may be grown on the one of the wafers, e.g., the base layer 102, and the other wafer, e.g., the intrinsic layer 104, will have the superconducting layer 108 deposited. The superconducting surface 108 may then be brought into contact with the oxide surface 110 and the wafers are bonded, where heat may be applied (e.g. as described above) to promote stable bonding. In yet other embodiments, no oxide layer may be deliberately grown and the superconducting layer may be grown on either the top of the substrate layer 102 or the bottom of the upper layer 104. After that, the superconductor 108 is brought into contact with the silicon on the other wafer, with heat potentially applied (e.g. as described above) to facilitate bonding. In still other embodiments, oxide may be present on both surfaces to be bonded. In various embodiments, the oxide layer as described above is not limited to silicon oxide and may include oxides of various other materials, such as aluminum oxide, and grown with methods such as CVD or plasma-enhanced CVD (PECVD).

An optional process 304 of the method 300 may include providing an oxide layer, such as e.g. the oxide layer 110 as described herein, over either the electrically conductive shield layer 108 as described herein for the embodiments where such a shield layer is implemented or over a base substrate of a doped semiconductor material, e.g. the base substrate 102 as described herein, for the embodiments where the conductive shield layer 108 is not implemented. In various embodiments, any suitable deposition techniques may be used for providing the oxide layer 110 in the process 304, and the oxide layer 110 may include any suitable oxide material, such as e.g. a silicon oxide or aluminum oxide.

The method 300 may then proceed to, or begin with if the optional processes 302 and 304 are not implemented, a process 306 where a layer of a substantially intrinsic semiconductor material, e.g. the intrinsic semiconductor layer 104 as described herein, is provided.

For the embodiments where the qubit substrate does not include the oxide layer 110 as described herein, and either includes the electrically conductive shield layer 108 in the form of a heavily doped semiconductor material or does not include such a shield layer at all (i.e. the intrinsic semiconductor layer 104 is provided directly over the base substrate 102), the intrinsic semiconductor layer 104 may be advantageously formed in the process 306 by epitaxial growth over the underlying semiconductor surface of either the electrically conductive shield layer 108 or the base substrate 102. Various techniques for epitaxially growing substantially intrinsic semiconductor layers are known in the art and, therefore, in the interests of brevity are not described here in detail.

For the embodiments where the qubit substrate either includes the oxide layer 110 or does not include the oxide layer but includes the electrically conductive shield layer 108 in the form of a metal or a metal alloy as described herein, the intrinsic semiconductor layer 104 may be advantageously formed in the process 306 by, first, being grown on a different substrate, and then transferred onto the oxide layer 110 or the metal/metal alloy of the electrically conductive shield layer 108 using any known techniques. For example, in some embodiments, wafer-to-wafer bonding may be used in such an embodiment of the process 306.

The method 300 may also include an optional process 308, in which a mechanical support layer, such as e.g. the mechanical support layer 106 as described herein, is provided on a side of the base substrate 102 opposite to that on which the intrinsic semiconductor layer is, or is to be, provided. In various embodiments of the method 300, the process 308 may be performed before or after any of the processes 302, 304, and 306.

In various embodiments, any suitable deposition techniques may be used for providing the mechanical support layer 106 in the process 308, such as e.g. CVD or spin-on techniques, and the mechanical support layer 106 may include any suitable material, such as e.g. silicon nitride, silicon oxide, silicon oxynitride, or carbon-doped silicon oxide.

The method 300 may also include an optional process 310, in which through vias are formed through the intrinsic semiconductor layer 104, e.g. the electrically conductive vias 112 as described herein, for the embodiments where such vias are implemented. In various embodiments, the conductive vias 112 may be formed in the process 310 using any suitable techniques. Examples of such techniques may include subtractive fabrication techniques, additive or semi-additive fabrication techniques, single Damascene fabrication techniques, dual Damascene fabrication techniques, or any other suitable technique. The intrinsic semiconductor material of the layer 104 can serve as a layer of insulator material that insulates various vias from one another. In some embodiments, additional layers, such as e.g. diffusion barrier layers or/and adhesion layers may be disposed between the conductive material(s) of the conductive vias 112 and proximate insulating material of the intrinsic semiconductor layer 104. Diffusion barrier layers may reduce diffusion of the conductive material(s) from the vias 112 into the intrinsic semiconductor layer 104. Adhesion layers may improve mechanical adhesion between the conductive material(s) of the vias 112 and the material of the intrinsic semiconductor layer 104.

A process 312 of the method 300 includes providing qubit devices/circuits on or in the package substrate formed as a result of performing previous processes of the method 300. Any known techniques for providing qubit devices/circuits on or in the package substrate 100 or 202 may be used in the process 312, all of which being within the scope of the present disclosure.

### Exemplary Qubit Devices

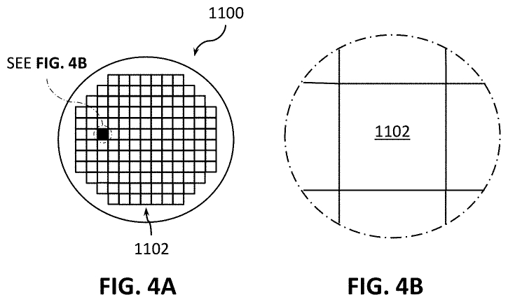

Quantum circuit assemblies/structures incorporating qubit substrates as described above may be included in any kind of qubit devices or quantum processing devices/structures. Some examples of such devices/structures are illustrated in FIGS. 4A-4B, 5, and 6.

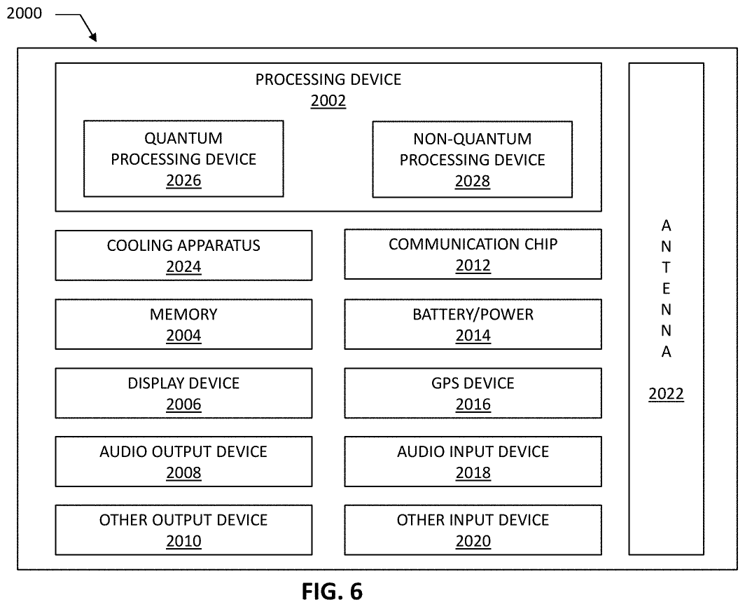

FIGS. 4A-4B are top views of a wafer 1100 and dies 1102 that may be formed from the wafer 1100, according to some embodiments of the present disclosure. The dies 1102 may include any of the quantum circuits disclosed herein, e.g., quantum circuits comprising superconducting qubits, spin qubits, or any combination of various types of qubits, and may be formed using as a foundation any of the qubit substrates described herein, such as e.g. the qubit substrates 100 or 202 as shown in FIGS. 1-2, or any further embodiments of these substrates as described herein. In particular, the wafer 1100 may be any the form of the qubit substrates as proposed herein, and may further include one or more dies 1102 having conventional and quantum circuit device elements formed on a surface of the wafer 1100. Each of the dies 1102 may be a repeating unit of a semiconductor product that includes any suitable conventional and/or quantum circuit qubit device. After the fabrication of the semiconductor product is complete, the wafer 1100 may undergo a singulation process in which each of the dies 1102 is separated from one another to provide discrete “chips” of the semiconductor product. A die 1102 may include one or more quantum circuits 100, including any supporting conductive circuitry to route electrical signals within the quantum circuits 100, as well as any other IC components. In some embodiments, the wafer 1100 or the die 1102 may include a memory device (e.g., a static random access memory (SRAM) device), a logic device (e.g., AND, OR, NAND, or NOR gate), or any other suitable circuit element. Multiple ones of these devices may be combined on a single die 1102. For example, a memory array formed by multiple memory devices may be formed on a same die 1102 as a processing device (e.g., the processing device 2002 of FIG. 6) or other logic that is configured to store information in the memory devices or execute instructions stored in the memory array.

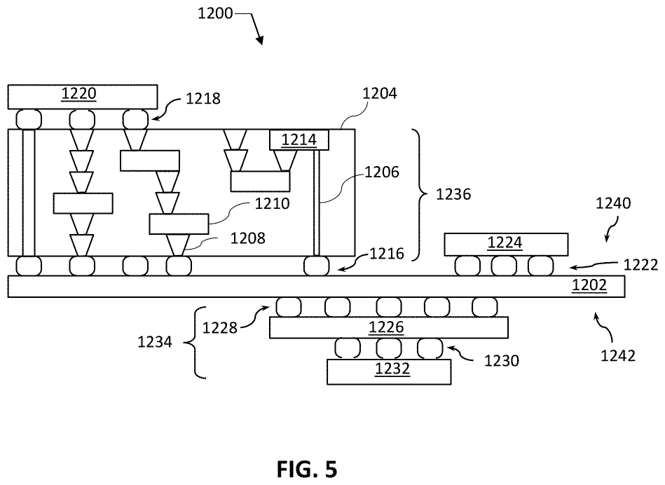

FIG. 5 is a cross-sectional side view of a device assembly 1200 that may include any of the embodiments of the qubit substrates disclosed herein. The device assembly 1200 includes a number of components disposed on a circuit board 1202. The device assembly 1200 may include components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. In other embodiments, the circuit board 1202 may be a package substrate or flexible board.

The IC device assembly 1200 illustrated in FIG. 5 may include a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 5), male and female portions of a socket, an adhesive, an underfill material, and/or any other suitable electrical and/or mechanical coupling structure.

The package-on-interposer structure 1236 may include a package 1220 coupled to an interposer 1204 by coupling components 1218. The coupling components 1218 may take any suitable form for the application, such as the forms discussed above with reference to the coupling components 1216. Although a single package 1220 is shown in FIG. 5, multiple packages may be coupled to the interposer 1204; indeed, additional interposers may be coupled to the interposer 1204. The interposer 1204 may provide an intervening substrate used to bridge the circuit board 1202 and the package 1220. The package 1220 may be a quantum circuit device package as described herein, e.g. a package including the qubit substrate 100 or 202 with any of the quantum circuits as described herein, or a combination thereof, or may be a conventional IC package, for example. Generally, the interposer 1204 may spread a connection to a wider pitch or reroute a connection to a different connection. For example, the interposer 1204 may couple the package 1220 (e.g., a die) to a ball grid array (BGA) of the coupling components 1216 for coupling to the circuit board 1202. In the embodiment illustrated in FIG. 5, the package 1220 and the circuit board 1202 are attached to opposing sides of the interposer 1204; in other embodiments, the package 1220 and the circuit board 1202 may be attached to a same side of the interposer 1204. In some embodiments, three or more components may be interconnected by way of the interposer 1204.

The interposer 1204 may be formed of an epoxy resin, a fiberglass-reinforced epoxy resin, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The device assembly 1200 may include a package 1224 coupled to the first face 1240 of the circuit board 1202 by coupling components 1222. The coupling components 1222 may take the form of any of the embodiments discussed above with reference to the coupling components 1216, and the package 1224 may take the form of any of the embodiments discussed above with reference to the package 1220. The package 1224 may be a package including one or more quantum circuits with qubits as described herein or may be a conventional IC package, for example. In some embodiments, the package 1224 may take the form of any of the embodiments of the quantum circuit 100 with any of the quantum circuit assemblies described herein.

The device assembly 1200 illustrated in FIG. 5 includes a package-on-package structure 1234 coupled to the second face 1242 of the circuit board 1202 by coupling components 1228. The package-on-package structure 1234 may include a package 1226 and a package 1232 coupled together by coupling components 1230 such that the package 1226 is disposed between the circuit board 1202 and the package 1232. The coupling components 1228 and 1230 may take the form of any of the embodiments of the coupling components 1216 discussed above, and the packages 1226 and 1232 may take the form of any of the embodiments of the package 1220 discussed above. Each of the packages 1226 and 1232 may be a qubit device package as described herein, e.g. by including the qubit substrates as described herein, or may be a conventional IC package, for example.

FIG. 6 is a block diagram of an exemplary quantum computing device 2000 that may include any of the quantum circuit assemblies formed using any of the qubit substrates disclosed herein. A number of components are illustrated in FIG. 6 as included in the quantum computing device 2000, but any one or more of these components may be omitted or duplicated, as suitable for the application. In some embodiments, some or all of the components included in the quantum computing device 2000 may be attached to one or more PCBs (e.g., a motherboard), and may be included in, or include, any of the quantum circuits with any of the quantum circuit assemblies described herein. In some embodiments, various ones of these components may be fabricated onto a single system-on-a-chip (SoC) die. Additionally, in various embodiments, the quantum computing device 2000 may not include one or more of the components illustrated in FIG. 6, but the quantum computing device 2000 may include interface circuitry for coupling to the one or more components. For example, the quantum computing device 2000 may not include a display device 2006, but may include display device interface circuitry (e.g., a connector and driver circuitry) to which a display device 2006 may be coupled. In another set of examples, the quantum computing device 2000 may not include an audio input device 2018 or an audio output device 2008, but may include audio input or output device interface circuitry (e.g., connectors and supporting circuitry) to which an audio input device 2018 or audio output device 2008 may be coupled.

The quantum computing device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may include a quantum processing device 2026 (e.g., one or more quantum processing devices), and a non-quantum processing device 2028 (e.g., one or more non-quantum processing devices). The quantum processing device 2026 may include one or more quantum circuit assemblies with quantum circuits provided on any of the qubit substrates disclosed herein, and may perform data processing by performing operations on the qubits that may be generated in the quantum circuits provided on any of the qubit substrates disclosed herein, and monitoring the result of those operations. For example, different qubits may be allowed to interact, the quantum states of different qubits may be set or transformed, and the quantum states of different qubits may be read. The quantum processing device 2026 may be a universal quantum processor, or specialized quantum processor configured to run one or more particular quantum algorithms. In some embodiments, the quantum processing device 2026 may execute algorithms that are particularly suitable for quantum computers, such as cryptographic algorithms that utilize prime factorization, encryption/decryption, algorithms to optimize chemical reactions, algorithms to model protein folding, etc. The quantum processing device 2026 may also include support circuitry to support the processing capability of the quantum processing device 2026, such as input/output channels, multiplexers, signal mixers, quantum amplifiers, and analog-to-digital converters.

As noted above, the processing device 2002 may include a non-quantum processing device 2028. In some embodiments, the non-quantum processing device 2028 may provide peripheral logic to support the operation of the quantum processing device 2026. For example, the non-quantum processing device 2028 may control the performance of a read operation, control the performance of a write operation, control the clearing of quantum bits, etc. The non-quantum processing device 2028 may also perform conventional computing functions to supplement the computing functions provided by the quantum processing device 2026. For example, the non-quantum processing device 2028 may interface with one or more of the other components of the quantum computing device 2000 (e.g., the communication chip 2012 discussed herein, the display device 2006 discussed herein, etc.) in a conventional manner, and may serve as an interface between the quantum processing device 2026 and conventional components. The non-quantum processing device 2028 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

The quantum computing device 2000 may include a memory 2004, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, the states of qubits in the quantum processing device 2026 may be read and stored in the memory 2004. In some embodiments, the memory 2004 may include memory that shares a die with the non-quantum processing device 2028. This memory may be used as cache memory and may include embedded dynamic random access memory (eDRAM) or spin transfer torque magnetic random access memory (STT-M RAM).

The quantum computing device 2000 may include a cooling apparatus 2024. The cooling apparatus 2024 may maintain the quantum processing device 2026, in particular the quantum circuits provided on any of the qubit substrates as described herein, at a predetermined low temperature during operation to avoid qubit decoherence and to reduce the effects of scattering in the quantum processing device 2026. This predetermined low temperature may vary depending on the setting; in some embodiments, the temperature may be 5 degrees Kelvin or less. In some embodiments, the non-quantum processing device 2028 (and various other components of the quantum computing device 2000) may not be cooled by the cooling apparatus 2030, and may instead operate at room temperature. The cooling apparatus 2024 may be, for example, a dilution refrigerator, a helium-3 refrigerator, or a liquid helium refrigerator.

In some embodiments, the quantum computing device 2000 may include a communication chip 2012 (e.g., one or more communication chips). For example, the communication chip 2012 may be configured for managing wireless communications for the transfer of data to and from the quantum computing device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other embodiments. The quantum computing device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some embodiments, a first communication chip 2012 may be dedicated to wireless communications, and a second communication chip 2012 may be dedicated to wired communications.

The quantum computing device 2000 may include battery/power circuitry 2014. The battery/power circuitry 2014 may include one or more energy storage devices (e.g., batteries or capacitors) and/or circuitry for coupling components of the quantum computing device 2000 to an energy source separate from the quantum computing device 2000 (e.g., AC line power).

The quantum computing device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display, for example.

The quantum computing device 2000 may include an audio output device 2008 (or corresponding interface circuitry, as discussed above). The audio output device 2008 may include any device that generates an audible indicator, such as speakers, headsets, or earbuds, for example.

The quantum computing device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The quantum computing device 2000 may include a GPS device 2016 (or corresponding interface circuitry, as discussed above). The GPS device 2016 may be in communication with a satellite-based system and may receive a location of the quantum computing device 2000, as known in the art.

The quantum computing device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The quantum computing device 2000 may include an other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The quantum computing device 2000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

### Select Examples

The following paragraphs provide some select examples of various ones of the embodiments disclosed herein.

Example 1 provides a quantum circuit assembly that includes a substrate and one or more quantum circuit components including a plurality of qubits over or in the substrate (i.e. said substrate is a “qubit substrate”). The substrate includes a base substrate of a doped semiconductor material having a dopant concentration of at least about 1·10¹⁴ atoms·cm⁻³, and a layer of a substantially intrinsic semiconductor material over the base substrate, the substantially intrinsic semiconductor material having a dopant concentration of less than about 1·10¹² atoms·cm⁻³.

Example 2 provides the quantum circuit assembly according to Example 1, where the base substrate is a bulk silicon substrate.

Example 3 provides the quantum circuit assembly according to Examples 1 or 2, where the base substrate has a resistivity below about 100 Ω·cm, including all values and ranges therein, e.g. between about 0.005 and 100 Ω·cm, or between about 8 and 80 Ω·cm. In the present disclosure, unless specified otherwise, resistivity values provided are those at room temperature.

Example 4 provides the quantum circuit assembly according to any one of the preceding Examples, where the substantially intrinsic semiconductor material is a substantially intrinsic silicon or a substantially intrinsic gallium arsenide.

Example 5 provides the quantum circuit assembly according to any one of the preceding Examples, where the substantially intrinsic semiconductor material has a resistivity of at least about 10000 Ω·cm, including all values and ranges therein, e.g. between about 10000 and 20000 Ω·cm.

Example 6 provides the quantum circuit assembly according to any one of the preceding Examples, where the substantially intrinsic semiconductor material has a thickness at least about 0.1 um, e.g. between about 0.1 and 400 um.

Example 7 provides the quantum circuit assembly according to any one of the preceding Examples, where the substrate further includes a layer of an electrically conductive, preferably substantially superconductive, material between the base substrate and the layer of the substantially intrinsic semiconductor material.

Example 8 provides the quantum circuit assembly according to Example 7, where the electrically conductive material includes a doped semiconductor material, e.g. a heavily doped semiconductor material with a dopant concentration of at least about 1·10²⁰ atoms·cm⁻³, including all values and ranges therein, e.g. between about 5·10²⁰ and 5·10²¹ atoms·cm⁻³, between about 1·10²¹ and 2.5·10²¹ atoms·cm⁻³.

Example 9 provides the quantum circuit assembly according to Example 7, where the electrically conductive material includes one or more of aluminum (Al), niobium (Nb), niobium nitride (NbN), titanium nitride (TiN), niobium titanium (NbTi), or niobium titanium nitride (NbTiN).

In various embodiments, room temperature resistivity of the electrically conductive material may be less than about 250·10⁻⁶ Ω·cm, including all values and ranges therein, e.g. between about 100·10⁻⁶ Ω·cm and 250·10⁻⁶ Ω·cm.

Example 10 provides the quantum circuit assembly according to any one of Examples 7-9, where the electrically conductive material has a thickness between about 0.02 and 0.5 um, including all values and ranges therein, e.g. between about 0.03 and 0.2 um.

Example 11 provides the quantum circuit assembly according to any one of Examples 7-10, where the substrate further includes an oxide layer between the layer of the electrically conductive material and the layer of the substantially intrinsic semiconductor material.

Example 12 provides the quantum circuit assembly according to Example 11, where the oxide layer includes silicon oxide or aluminum oxide. In other examples, other suitable oxides may be used.

Example 13 provides the quantum circuit assembly according to Examples 11 or 12, where the oxide layer has a thickness between about 20 and 2000 nm.

Example 14 provides the quantum circuit assembly according to any one of Examples 7-13, where the substrate includes a plurality of electrically conductive vias extending between (i.e. from) a first face and an opposing second face of the layer of the intrinsic semiconductor material.

Example 15 provides the quantum circuit assembly according to Example 14, where a width of each of the plurality of electrically conductive vias is less than about 100 um, including all values and ranges therein, e.g. less than 80 um.

Example 16 provides the quantum circuit assembly according to any one of Examples 1-6, where the substrate further includes an oxide layer between the base substrate and the layer of the substantially intrinsic semiconductor material.

Example 17 provides the quantum circuit assembly according to Example 16, where the oxide layer includes one or more of silicon oxide and aluminum oxide.

Example 18 provides the quantum circuit assembly according to Examples 16 or 17, where the oxide layer has a thickness between about 20 and 2000 nm.

Example 19 provides the quantum circuit assembly according to any one of the preceding Examples, where the substrate further includes a mechanical support layer on a side of the base substrate opposite a side that over which the layer of the substantially intrinsic semiconductor material is provided.

Example 20 provides the quantum circuit assembly according to Example 19, where the mechanical support layer is a layer including silicon and nitrogen (e.g. a layer of silicon nitride).

Example 21 provides the quantum circuit assembly according to Examples 19 or 20, where the mechanical support layer has a thickness between about 0.1 and 1 um, including all values and ranges therein, e.g. between about 0.2 and 0.8 um, or between about 0.2 and 0.5 um.

Example 22 provides a method of manufacturing a quantum circuit assembly. The method includes providing a substrate that has a base substrate of a doped semiconductor material having a dopant concentration of at least about 1·10¹⁴ atoms·cm⁻³, and a layer of a substantially intrinsic semiconductor material over the base substrate, the substantially intrinsic semiconductor material having a dopant concentration of less than about 1·10¹² atoms·cm⁻³. The method also includes providing a plurality of qubits over or in the substrate.

Example 23 provides the method according to Example 22, where providing the substrate includes epitaxially growing the layer of the substantially intrinsic semiconductor material over the base substrate.

Example 24 provides the method according to Example 22, where the base substrate includes an oxide layer over the doped semiconductor material, and where providing the substrate includes attaching the layer of the substantially intrinsic semiconductor material to the oxide layer, e.g. using wafer-to-wafer permanent bonding techniques as known in the art.

Example 25 provides the method according to any one of Examples 22-24, where providing the substrate further includes providing a layer of an electrically conductive, preferably substantially superconductive, material between the base substrate and the layer of the substantially intrinsic semiconductor material.

Example 26 provides the method according to Example 25, where providing the layer of the electrically conductive material includes depositing the electrically conductive material over the base substrate using atomic layer deposition (ALD), chemical vapor deposition (CVD), physical vapor deposition (PVD) (e.g. evaporative deposition, magnetron sputtering, or e-beam deposition), or electroplating, possibly in combination with patterned using any known patterning techniques, e.g. photolithographic patterning.

Example 27 provides the method according to any one of Examples 22-26, where providing the substrate further includes providing a mechanical support layer on a side of the base substrate opposite a side that over which the layer of the substantially intrinsic semiconductor material is provided.

Example 28 provides the method according to Example 27, where providing the mechanical support layer includes depositing one or more of a layer including silicon and nitrogen (e.g. a layer of silicon nitride), a layer including silicon, oxygen, and nitrogen (e.g., a layer of silicon oxynitride), a layer including silicon and oxygen (e.g. a layer of silicon oxide), or a layer including of carbon-doped silicon oxide (CDO), each of which could be deposited using CVD or spin-on techniques as known in the art.

In various Examples, the substrate in Example provides the method according to any one of the preceding Examples may be the substrate according to any one of the Examples 1-21.

Example 29 provides a quantum computing device that includes a quantum processing device and a memory device. The quantum processing device includes a plurality of quantum circuit components (each of which can include one or more qubits) provided over a substrate that includes a base substrate of a doped semiconductor material having a dopant concentration of at least about 1·10¹⁴ atoms per cubic centimeter (atoms·cm⁻³), and a layer of a substantially intrinsic semiconductor material over the base substrate, the substantially intrinsic semiconductor material having a dopant concentration of less than about 1·10¹² atoms·cm⁻³. The memory device is configured to store data generated by the plurality of quantum circuit components during operation of the quantum processing device.

Example 30 provides the quantum computing device according to Example 29, further including a non-quantum processing device, coupled to the quantum processing device.

Example 31 provides the quantum computing device according to Examples 29 or 30, further including a cooling apparatus configured to maintain a temperature of the plurality of quantum circuit components below 5 degrees Kelvin.

Example 32 provides the quantum computing device according to any one of Examples 29-31, where the memory device is further configured to store instructions for a quantum computing algorithm to be executed by the quantum processing device.

Example 33 provides a quantum circuit assembly that includes a substrate and one or more quantum circuit components including a plurality of qubits over or in the substrate (i.e. said substrate is a “qubit substrate”). The substrate includes an upper portion and a lower portion, a layer of an electrically conductive, preferably substantially superconductive, material separating the upper portion and the lower portion, and a plurality of electrically conductive vias extending between (i.e. from) a first face and an opposing second face of the layer of the upper portion of the substrate.

Example 34 provides the quantum circuit assembly according to Example 33, where a height of each of the plurality of electrically conductive vias is less than about 400 um, including all values and ranges therein, e.g. less than 200 um.

Example 35 provides the quantum circuit assembly according to Examples 33 or 34, where the electrically conductive material includes a doped semiconductor material, e.g. a heavily doped semiconductor material with a dopant concentration of at least about 1·10²⁰ atoms·cm⁻³, including all values and ranges therein, e.g. between about 5·10²⁰ and 5·10²¹ atoms·cm⁻³, between about 1·10²¹ and 2.5·10²¹ atoms·cm⁻³.

Example 36 provides the quantum circuit assembly according to Examples 33 or 34, where the electrically conductive material includes one or more of aluminum (Al), niobium (Nb), niobium nitride (NbN), titanium nitride (TiN), niobium titanium (NbTi), or niobium titanium nitride (NbTiN).

Again, in various embodiments, room temperature resistivity of the electrically conductive material may be less than about 250·10⁻⁶ Ω·cm, including all values and ranges therein, e.g. between about 100·10⁻⁶ Ω·cm and 250 ·10⁻⁶ Ω·cm.

Example 37 provides the quantum circuit assembly according to any one of Examples 33-36, where the electrically conductive material has a thickness between about 0.02 and 0.5 um, including all values and ranges therein, e.g. between about 0.03 and 0.2 um.

Example 38 provides the quantum circuit assembly according to any one of Examples 33-37, where the substrate further includes an oxide layer between the layer of the electrically conductive material and the upper portion of the substrate.

Example 39 provides the quantum circuit assembly according to any one of Examples 33-38, where the upper portion includes a semiconductor material having a dopant concentration of less than about 1·10¹² atoms·cm⁻³, and the lower portion includes a semiconductor material having a dopant concentration of at least about 1·10¹⁴ atoms·cm⁻³.

Example 40 provides the quantum circuit assembly according to any one of Examples 33-39, where the upper portion has a resistivity of at least about 10000 Ω·cm, including all values and ranges therein, e.g. between about 10000 and 20000 Ω·cm, or/and the lower portion has a resistivity below about 100 Ω·cm, including all values and ranges therein, e.g. between about 0.005 and 100 Ω·cm, or between about 8 and 80 Ω·cm.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A quantum circuit assembly comprising:
a substrate; and
a plurality of qubits over or in the substrate,
wherein the substrate comprises a base substrate of a doped semiconductor material having a dopant concentration of at least 1·10¹⁴ atoms per cubic centimeter (atoms·cm⁻³), and a layer of an intrinsic semiconductor material over the base substrate, the intrinsic semiconductor material having a dopant concentration of less than 1·10¹² atoms·cm⁻³.

2. The quantum circuit assembly according to claim 1, wherein the base substrate is a bulk silicon substrate.

3. The quantum circuit assembly according to claim 1, wherein the base substrate has a resistivity below 100 ohm·centimeter.

4. The quantum circuit assembly according to claim 1, wherein the intrinsic semiconductor material is an intrinsic silicon or an intrinsic gallium arsenide.

5. The quantum circuit assembly according to claim 1, wherein the intrinsic semiconductor material has a resistivity of at least 10000 ohm·centimeter.

6. The quantum circuit assembly according to claim 1, wherein the intrinsic semiconductor material has a thickness at least 0.1 micrometers.

7. The quantum circuit assembly according to claim 1, wherein the substrate further comprises a layer of an electrically conductive material between the base substrate and the layer of the intrinsic semiconductor material.

8. The quantum circuit assembly according to claim 7, wherein the electrically conductive material comprises a doped semiconductor material.

9. The quantum circuit assembly according to claim 7, wherein the electrically conductive material has a thickness between 0.02 and 0.5 micrometers.

10. The quantum circuit assembly according to claim 7, wherein the substrate further comprises an oxide layer between the layer of the electrically conductive material and the layer of the intrinsic semiconductor material.

11. The quantum circuit assembly according to claim 10, wherein the oxide layer has a thickness 20 and 2000 nanometers.

12. The quantum circuit assembly according to claim 7, wherein the substrate includes a plurality of electrically conductive vias extending between a first face and an opposing second face of the layer of the intrinsic semiconductor material.

13. The quantum circuit assembly according to claim 12, wherein a width of each of the plurality of electrically conductive vias is less than 100 micrometers.

14. The quantum circuit assembly according to claim 1, wherein the substrate further comprises a mechanical support layer on a side of the base substrate opposite a side that over which the layer of the intrinsic semiconductor material is provided, wherein the mechanical support layer is a layer comprising silicon and nitrogen and has a thickness between 0.1 and 1 micrometers.

15. A method of manufacturing a quantum circuit assembly, the method comprising:
providing a substrate comprising:
a base substrate of a doped semiconductor material having a dopant concentration of at least 1·10¹⁴ atoms per cubic centimeter (atoms·cm⁻³), and
a layer of an intrinsic semiconductor material over the base substrate, the intrinsic semiconductor material having a dopant concentration of less than 1·10¹² atoms·cm⁻³; and
providing a plurality of qubits over or in the substrate.

16. The method according to claim 15, wherein providing the substrate comprises epitaxially growing the layer of the intrinsic semiconductor material over the base substrate.

17. The method according to claim 15, wherein the base substrate includes an oxide layer over the doped semiconductor material, and wherein providing the substrate comprises attaching the layer of the intrinsic semiconductor material to the oxide layer.

18-19. (canceled)

20. A quantum circuit assembly comprising:
a substrate; and
a plurality of qubits over or in the substrate,
wherein the substrate comprises:
an upper portion and a lower portion,
a layer of an electrically conductive material separating the upper portion and the lower portion, and
a plurality of electrically conductive vias extending between a first face and an opposing second face of the layer of the upper portion.

21. The quantum circuit assembly according to claim 20, wherein a height of each of the plurality of electrically conductive vias is less than 400 micrometers.

22-24. (canceled)

25. The quantum circuit assembly according to claim 20, wherein the upper portion has a resistivity of at least 10000 ohm centimeter (Ω·cm), or/and the lower portion has a resistivity below 100 Ω·cm.
